(19) United States
(12) Patent Application Publication
(10) Pub. No.: US 2008/0297171 A1
(43) Pub. Date: Dec. 4, 2008

(54) TRANSCEIVER SYSTEM THAT ESTIMATES A VOLTAGE STANDING WAVE RATIO

(76) Inventors: Christopher D. Ruppel, Carmel, IN (US); Todd M. Brandenburg, Kokomo, IN (US); Steven P. Alverson, Cicero, IN (US); Roger A. McDanell, Carmel, IN (US)

Correspondence Address: DELPHI TECHNOLOGIES, INC., M/C 480-410-202, PO BOX 5052, TROY, MI, 48007, US

(21) Appl. No.: 11/755,290

(22) Filed: May 30, 2007

(51) Int. Cl. G01R 27/02

(52) U.S. Cl. 324/607

(57) ABSTRACT

A transceiver system and method determining a voltage standing wave ratio (VSWR) is provided. The system includes at least one amplifier, a filter bank, a plurality of detectors, and at least one processor. The at least one amplifier receives an input signal. The filter bank is in electrical communication with the at least one amplifier. The plurality of detectors are in electrical communication with the filter bank, where a first detector of the plurality of detectors is in electrical communication with a first portion of the filter bank, and a second detector of the plurality of detectors is in electrical communication with a second portion of the filter bank. The at least one processor is in electrical communication with the plurality of detectors, and estimates a VSWR based upon voltages detected by the first and second detectors.

### TECHNICAL FIELD

The present invention generally relates to a transceiver system, and more particularly, a transceiver system that estimates a voltage standing wave ratio.

### BACKGROUND OF THE DISCLOSURE

Generally, transceiver systems need to connect the necessary receive and transmit circuits to an antenna system in order to receive and transmit signals. Typically, the efficiency of the antenna and cable design and the matching of the transmission cable to the transmission amplifier and antenna of the transceiver system can be determined based upon the voltage standing wave ratio (VSWR). The VSWR quantifies the undesirable signal reflections within the lines of the transceiver system, which corresponds to the inefficiency of the transceiver system. Thus, a perfectly designed transceiver system with a transmission cable that is well matched to the transmit amplifier and the antenna results in no signal reflections and uniform distribution of the signal magnitudes along the transmission line length.

Generally, the hardware for measuring the VSWR transceiver systems that operate at very high frequencies are expensive and bulky. Typically, the hardware is expensive and bulky because of the need for directional couplers or bridge circuits, which can be dimensionally large and/or have significant losses when operating in the high frequency (HF), very high frequency (VHF), and ultra high frequency (UHF) wavelengths, and may require large-gauge component conductors or bulky ferrite inductor cores. Additionally, such hardware may also require radio frequency (RF) switching elements to enable/disable the VSWR measurement circuitry under certain operating conditions.

### SUMMARY OF THE INVENTION

According to one aspect of the present invention, a transceiver system includes at least one amplifier, a filter bank, a plurality of detectors, and at least one processor. The at least one amplifier receives an input signal. The filter bank is in electrical communication with the at least one amplifier. The plurality of detectors are in electrical communication with the filter bank, where a first detector of the plurality of detectors is in electrical communication with a first portion of the filter bank and a second detector of the plurality of detectors is in electrical communication with a second portion of the filter bank. The at least one processor is in electrical communication with the plurality of detectors, and estimates a voltage standing wave ratio (VSWR) based upon voltages detected by at least the first and second detectors.

According to another aspect of the present invention, a transceiver system for receiving and transmitting signals in approximately a Very High Frequency (VHF) band includes at least one amplifier, a filter bank, a plurality of detectors, an analog-to-digital converter (ADC), and at least one processor. The at least amplifier receives an input signal. The filter bank is in electrical communication with the at least one amplifier. The plurality of detectors are in electrical communication with the filter bank, where the first detector of the plurality of detectors is in electrical communication with a first portion of the filter bank, and a second detector of the plurality of detectors is in electrical communication with a second portion of the filter bank. The plurality of detectors discretely tap the filter bank. The ADC is in electrical communication with the plurality of detectors, where values for the voltages detected by the plurality of detectors are determined. The at least one processor is in electrical communication with the ADC, and estimates a VSWR based upon the values.

According to yet another aspect of the present invention, a method of determining a VSWR in a transceiver system includes the steps of receiving an input signal by at least one amplifier, and filtering the input signal by a filter bank, wherein the filter bank is in electrical communication with the at least one amplifier. The method further includes the steps of detecting a first voltage in a first portion of the filter bank by a first detector of the plurality of detectors, detecting a second voltage in a section portion of the filter bank by a second detector of the plurality of detectors, and estimating the VSWR based upon the first voltage and the second voltage.

These and other features, advantages and objects of the present invention will be further understood and appreciated by those skilled in the art by reference to the following specification, claims and appended drawings.

### BRIEF DESCRIPTION OF THE DRAWINGS

The present invention will now be described, by way of example, with reference to the accompanying drawings, in which:

FIG. 1 is a block diagram of a transceiver system in accordance with one embodiment of the present invention;

FIG. 2 is a chart illustrating sample voltage standing wave ratio estimates compared to actual voltage standing wave ratios in accordance with one embodiment of the present invention; and

FIG. 3 is a flow chart illustrating a method of determining a voltage standing wave ratio in a transceiver system in accordance with one embodiment of the present invention.

### DESCRIPTION OF PREFERRED EMBODIMENTS

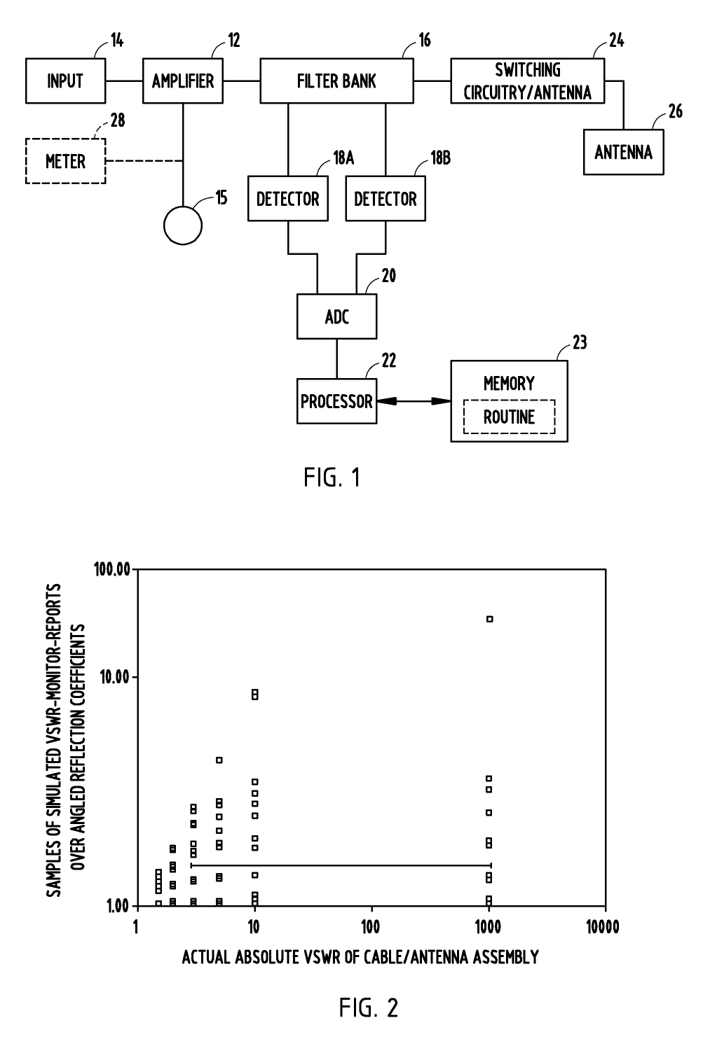

In reference to FIG. 1, a transceiver system is generally shown at reference identifier 10. The transceiver system 10 includes at least one amplifier 12 that receives an input 14. According to one embodiment, the input 14 signal is an un-amplified transmit radio frequency (RF) signal, and the amplifier 12 increases the power of the input 14 signal to approximately the full amplified power for the type of amplifier 12 that is being used. A power source 15, such as, but not limited to, a battery or the like, can be in electrical communication with the amplifier 12 to provide power to the amplifier 12, such that the amplifier 12 can amplify the input 14 signal. As disclosed, the power source 15 can be a direct current (DC) power source. Alternatively, the power source 15 can be an alternating current (AC) power source, where a rectifier is in electrical communication between the amplifier 12 and power source 15, such that the power supplied to the amplifier 12 is DC power. Generally, by increasing the power of the signal, the harmonics of the signal are also amplified.

The transceiver system 10 further includes a filter bank 16 that is in electrical communication with the amplifier 12, and a plurality of detectors in electrical communication with the filter bank 16. Typically, the filter bank 16 is a low-pass filter that filters out the unacceptable harmonics to a suitable level. The plurality of detectors includes at least a first detector 18A and a second detector 18B, which discretely tap the filter bank 16 to determine a voltage for each of the first and second detectors 18A, 18B.

In a disclosed embodiment, the first and second detectors 18A, 18B are voltage detectors, where the first detector 18A is in electrical communication with a first portion of the filter bank 16, and the second detector 18B is in electrical communication with a second portion of the filter bank 16. By way of explanation and not limitation, the first voltage detector 18A detects the voltage as the signal enters the filter bank 16, and the second voltage detector 18B detects the voltage as the signal exits the filter bank 16, and these circuit taps correspond to tapping a discrete-equivalent transmission line at two physical points that are spaced from one another. The first and second detectors 18A, 18B lightly or discretely tap the filter bank 16 by including a small coupling capacitor, such as a 1.8 pico-Farad (pF). The first and second detectors 18A, 18B can also include a rectifier, a resistor-divider, and a resistor-capacitor (R-C) filter, such that the outputs of the first and second detectors 18A, 18B are direct current (DC) voltages. Based upon the voltages detected by the first and second detectors 18A, 18B, a voltage standing wave ratio (VSWR) is estimated, as described in greater detail herein. By determining the voltage at portions of the transceiver system 10 circuitry that are tuned RF circuitry, the VSWR can be estimated under normal operating conditions of the transceiver system 10.

By way of explanation and not limitation, the input 14 is an RF signal, and the amplifier 12 is a Class C RF transmit amplifier. The filter bank 16 can be a low-pass filter, such as an Elliptic filter or Butterworth filter. According to a disclosed embodiment, the transceiver system 10 can transmit and receive signals that are approximately within the Very High Frequency (VHF) band, such as signals at approximately 30 megahertz (MHz) to 300 MHz.

According to one embodiment, the transceiver system 10 includes an analog-to-digital converter (ADC) 20 that is in communication with the first and second detectors 18A, 18B. The ADC 20 determines values, such as digital values, for the voltages that are detected by the first and second detectors 18A, 18B. A processor 22 is in communication with the ADC 20, and receives the values determined by the ADC 20. The values received by the processor 22 are used to estimate the VSWR of the transceiver system 10. Typically, the processor 22 estimates the VSWR by choosing the larger value that corresponds to the larger voltage detected by the first detector 18A or second detector 18B, and uses the larger value as the numerator of the ratio between the two values. According to a disclosed embodiment, the processor 22 is in electrical communication with a memory device 23 that contains at least one routine, such as a software routine, so that the VSWR can be estimated, as described in greater detail herein. It should be appreciated by those skilled in the art that the processor 22 can be analog circuitry for processing the voltages obtained by the first and second detectors 18A, 18B in order to determine if the transceiver system 10 is functioning properly.

Additionally, the transceiver system 10 can include switching circuitry 24 and at least one antenna 26. Typically, the switching circuitry is used to switch the transceiver system 10 from a transmitting to a receiving state, so that the antenna 24 transmits or receives signals accordingly. It should be appreciated by those skilled in the art that the switching circuitry 24, antenna 26, and the matching or connection of the switching circuitry 24 and antenna 26 to the amplifier 12 may affect the VSWR. Typically, the antenna 26 is designed, such that the antenna 26 is well-matched to the filter bank 16 and other components in the transceiver system 10.

In reference to FIG. 2, the chart illustrates the VSWR estimates of the transceiver system 10 compared to the actual VSWR estimated in the transceiver system 10. Generally, since the first and second detectors 18A, 18B discretely tap the filter bank 16 in order to determine a voltage, true VSWRs cannot necessarily be determined with perfect accuracy. However, the voltage values determined by the first and second detectors 18A, 18B and the VSWR estimated based upon those detected voltages are sufficient to detect field-degradation or cable-mismatch situations at a single point in time or field-degradation or cable-mismatch situations over a period of time, and thus, alert of potential problems in the transceiver system 10.

According to a disclosed embodiment, the horizontal line extending across the chart (FIG. 2) illustrates that there is approximately a twenty-four percent (24%) chance, over the spectrum of antenna/cable VSWR possibilities, that a random VSWR estimation will represent that the transceiver system 10 is functioning significantly better than the actual VSWR. Generally, well-designed transceiver systems may operate with a small target VSWR, such as between 1.0 and 2.0, and increasingly larger VSWR figures are typically detrimental to system efficiency in a logarithmic sense. For purposes of explanation and not limitation, a VSWR degradation from 1.5 to 3.0 is approximately as significant as a VSWR degradation from 3.0 to 6.0. FIG. 2 illustrates that a disclosed embodiment can provide a useful high-VSWR estimate when the actual VSWR is large, but at some angles of transmission-line reflection coefficients, the estimated VSWR can be lower than the actual VSWR.

According to one embodiment, the estimated VSWR can also compensate for temperature drifts, changes in the amplifier 12 power supply, the like, or a combination thereof. For example, the voltages detected by the first detector 18A and the second detector 18B can be normalized, such that the voltage value detected by the first detector 18A is divided by a predetermined stored voltage value typically taken at room-temperature, known-accurate load conditions, and a nominal power supply voltage. Likewise, the voltage detected by the second detector 18B is divided by a predetermined voltage value taken at room-temperature, known-accurate load conditions, and a nominal power supply voltage. Temperature and power supply factors generally act similarly at both voltages, so the normalizations remove temperature and power supply influences from the estimated VSWR. The normalized detected voltage values remain influenced by RF load conditions, and are then used to estimate the VSWR.

Typically, the accuracy of the VSWR can be increased by using a greater number of detectors that tap the elements of the transceiver system 10 at different locations, by using different transmit frequencies, monitoring the transceiver system 10 power supply, or a combination thereof. When a greater number of detectors are used or a greater number of measurement taps are made, the VSWR estimation may be based upon the larger ratio of voltages obtained. For purposes of explanation and not limitation, the maximum tapped voltage level can be divided by the minimum tapped voltage level.

According to an alternate embodiment, using transmit signals at different frequencies can cause slightly different effective phase delays in the elements of the filter bank 16. By estimating the VSWR at a first transmit frequency, and then estimating the VSWR based upon a different transmit frequency in the transceiver system 10, the accuracy of the overall estimated VSWR is increased. According to one embodiment, the highest estimated VSWRs may be considered the more accurate VSWR estimates. Generally, the first and second frequencies are both within the transceiver system 10 determined band. Alternatively, the DC current consumption of the transceiver system 10 from its power supply can be monitored to be determined if the current is above or below normal current levels during poor VSWR transmit conditions. By way of explanation and not limitation, if the estimated VSWR is low, but the transceiver system 10 current level is abnormal, then one can be alerted to further evaluate the transceiver system 10. According to one embodiment, an amp-meter 28 can be in electrical communication between the power supply 15 and the amplifier 12 in order to measure the current.

According to a disclosed embodiment, the differing conditions of the RF circuitry system, RF cable system, antenna 26 system are assessed. It should be appreciated by those skilled in the art that the design-optimization of the amplifier 12 can also need an accurate impedance match between the amplifier 12, the filter bank 16, and other components of the transceiver system 10. Typically, by detecting voltages at points through the filter bank 16, the detected voltages can be used to estimate the matching accuracy between the amplifier 12 and the filter bank 16. For purposes of explanation and not limitation, if a known-accurate system of RF switching circuitry, RF cable, and antenna 26 load is established, then the estimated VSWR can be used to assess or determine the efficiency of the impedance match between the amplifier 12 and filter bank 16. The estimated VSWR can be useful to the design of the amplifier 12, when the amplifier 12 is a high-power amplifier because, typically, high-power amplifier circuit operation is not conducive to other impedance-measurement instruments, such as RF network analyzers.

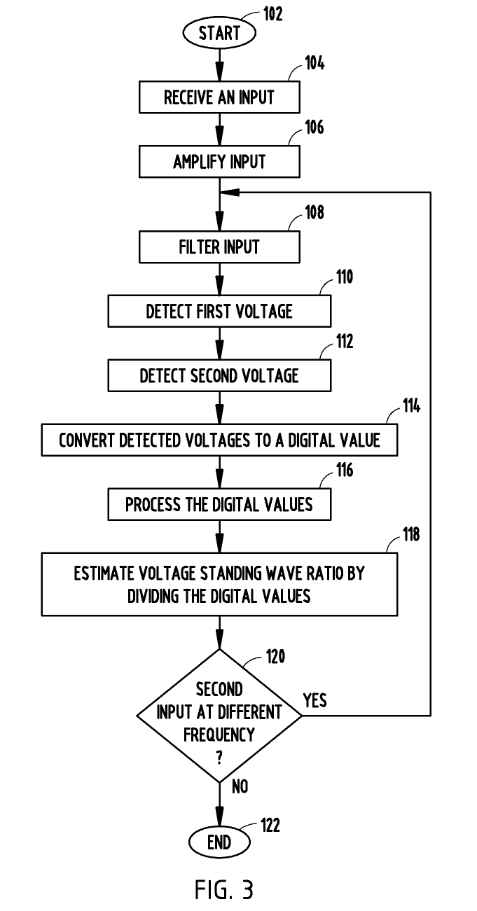

In reference to FIGS. 1 and 3, a method for estimating the VSWR in a transceiver system 10 is generally shown in FIG. 3 at 100. The method 100 starts at step 102, and proceeds to step 104, where an input 14 signal is received. At step 106, the input 14 signal is amplified by the amplifier 12. At step 108, the input is filtered by the filter bank 16.

The method 100 then proceeds to step 110, where a first voltage is detected by the first detector 18A, and at step 112, a second voltage is detected by the second detector 18B. The ADC 20 converts the detected voltages to a corresponding digital value at step 114. At step 116, the processor 22 processes the value, and a VSWR is estimated at step 118. According to a disclosed embodiment, the VSWR is estimated by calculating a ratio between the digital values, where the larger of the digital values is the numerator in the calculation. Thus, the ratio is equal to or greater than one.

At decision step 120, it is determined if a second input 14 at a different frequency is present in the transceiver system 10. If it is determined that a second input 14 at a different frequency is present at decision step 120, the method 100 proceeds to step 106. However, if it is determined that a second input 14 at a different frequency is not present at decision step 120, the method 100 ends at step 122. According to one embodiment, the processor 22 performs steps 116-120.

By way of explanation and not limitation, the transceiver system 10 can be regulated to only transmit signals at a specific channel or frequency band at a particular time. Thus, at a particular time, the transceiver system 10 may only be able to estimate a VSWR at a single frequency. However, over the course of a time period, if the transceiver system 10 is capable of transmitting signals at different channels or frequency bands, the transceiver system 10 can compare VSWR estimates at different frequencies over the period of time. If a VSWR estimate at one of the different frequencies is large, thus indicating the transceiver system 10 is operating under poor operating conditions, the transceiver system 10 can use the higher VSWR estimate, and one can be alerted of the undesirable operating conditions. Alternatively, if the VSWR estimates for different frequencies are low, thus indicating the transceiver system 10 is operating under desirable conditions, but the current measurement of the transceiver system 10 power supply is abnormal, one can be alerted to further reevaluate the operating conditions of the transceiver system 10.

According to the disclosed embodiment, in operation, the transceiver system 10 can be used in a vehicle or other mobile device or apparatus, where the transceiver system 10 is subject to different environmental conditions, which can affect the functionality and efficiency of the transceiver system 10. Thus, the environmental conditions, among other things, can affect the functionality of the components of the transceiver system 10 over time, and by having the components to estimate the VSWR included in the transceiver system 10, the VSWR can be continuously monitored in order to determine when the transceiver system 10 is functioning undesirably.

Advantageously, the transceiver system 10 can contain the necessary components in order to estimate and monitor or analyze the VSWR in the transceiver system 10, such that the VSWR can be used to alert when the transceiver system 10 is functioning under undesirable operating conditions. Thus, a secondary device that is mounted to the transceiver system 10 is not required. Additionally, by lightly or discretely tapping the filter bank 16 by the first and second detectors 18A, 18B, the size and effect of the components needed to estimate the VSWR are minimized, which increases the efficiency and makes the VSWR detection components, in combination with the transceiver system 10, economical. Further, by lightly or discretely tapping the filter bank 16, the VSWR can be determined under normal operating conditions for the transceiver system 10. Thus, it should be appreciated by those skilled in the art that the transceiver system 10 can be used on any system, where it is desirable to detect and monitor the VSWR in order to determine if the transceiver system 10 is damaged or functioning inefficiently.

The above description is considered that of the preferred embodiments only. Modifications of the invention will occur to those skilled in the art and to those who make or use the invention. Therefore, it is understood that the embodiments shown in the drawings and described above are merely for illustrative purposes and not intended to limit the scope of the invention, which is defined by the following claims as interpreted according to the principles of patent law, including the doctrine of equivalents.

1. A transceiver system comprising:
at least one amplifier, wherein said at least one amplifier receives an input signal;
a filter bank in electrical communication with said at least one amplifier;
a plurality of detectors in electrical communication with said filter bank, wherein a first detector of said plurality of detectors is in electrical communication with a first portion of said filter bank and a second detector of said plurality of detectors is in electrical communication with a second portion of said filter bank; and
at least one processor in electrical communication with said plurality of detectors for processing said detected voltages, and estimating a voltage standing wave ratio (VSWR) based upon voltages detected by at least said first and second detectors.

2. The transceiver system of claim 1, wherein received and transmitted signals are in approximately the Very High Frequency (VHF) band.

3. The transceiver system of claim 1 further comprising an analog-to-digital converter (ADC) in electrical communication with said plurality of detectors, wherein values for said voltages detected by said plurality of detectors are determined and communicated to said processor for estimating said VSWR.

4. The transceiver system of claim 1, wherein said VSWR is analyzed to determine if said transceiver system is functioning under undesirable operating conditions.

5. The transceiver system of claim 1, wherein said processor normalizes said VSWR to compensate for at least one of temperature drifts in said plurality of detectors and changes in said amplifier power supply.

6. The transceiver system of claim 1, wherein said plurality of detectors discretely tap said filter bank.

7. The transceiver system of claim 1, wherein said transceiver system is used on a vehicle.

8. The transceiver system of claim 1, wherein a first VSWR is estimated based upon said voltages of said plurality of detectors at a first frequency and a second VSWR is estimated based upon said voltages of said plurality of detectors at a second frequency.

9. A transceiver system for receiving and transmitting signals in approximately the Very High Frequency (VHF) band comprising:
at least one amplifier, wherein said at least one amplifier receives an input signal;
a filter bank in electrical communication with said at least one amplifier;
a plurality of detectors in electrical communication with said filter bank, wherein said plurality of detectors discretely tap said filter bank, such that a first detector of said plurality of detectors is in electrical communication with a first portion of said filter bank and a second detector of said plurality of detectors is in electrical communication with a second portion of said filter bank;
an analog-to-digital converter (ADC) in electrical communication with said plurality of detectors, wherein values for said voltages detected by said plurality of detectors are determined; and
at least one processor in electrical communication with said ADC for processing said detected voltages, and estimating a voltage standing wave ratio (VSWR) based upon said values determined by said ADC.

10. The transceiver system of claim 9, wherein said VSWR is analyzed to determine if said transceiver system is functioning under undesirable operating conditions.

11. The transceiver system of claim 9, wherein said processor normalizes said VSWR to compensate for at least one of temperature drifts in said plurality of detectors and changes in said amplifier power supply.

12. The transceiver system of claim 9 further comprising at least one antenna in electrical communication with said filter bank.

13. The transceiver system of claim 9, wherein said transceiver system is used on a vehicle.

14. The transceiver system of claim 9, wherein a first VSWR is estimated based upon said voltages of said plurality of detectors at a first frequency and a second VSWR is estimated based upon said voltages of said plurality of detectors at a second frequency.

15. A method of estimating a voltage standing wave ratio (VSWR) in a transceiver system, said method comprising the steps of:
receiving an input signal by at least one amplifier;
filtering said input signal by a filter bank, wherein said filter bank is in electrical communication with said at least one amplifier;
detecting a first voltage in a first portion of said filter bank by a first detector of a plurality of detectors;
detecting a second voltage in a second portion of said filter bank by a second detector of said plurality of detectors; and
estimating a VSWR based upon said first voltage and said second voltage.

16. The method of claim 15 further comprising the step of analyzing said VSWR to determine if said transceiver system is functioning under undesirable operating conditions.

17. The method of claim 15 further comprising the step of receiving said voltages from said plurality of detectors by an analog-to-digital converter (ADC), wherein said ADC determines a value for each of said detected voltages, and said values are processed by a processor to estimate said VSWR.

18. The method of claim 17 further comprising the step of normalizing said values by said processor, wherein said processor compensates for at least one of temperature drifts in said plurality of detectors and changes in said amplifier power supply.

19. The method of claim 15 further comprising the step of estimating a first VSWR based upon said voltages of said plurality of detectors at a first frequency and estimating a second VSWR based upon said voltages of said plurality of detectors at a second frequency.

20. The method of claim 15 further comprising the step of receiving and transmitting signals by said transceiver system, wherein said signals are in approximately the Very High Frequency (VHF) band.
